(19) United States
(12) Patent Application Publication
(10) Pub. No.: US 2022/0014696 A1
(43) Pub. Date: Jan. 13, 2022

(54) IMAGE SENSOR WITH DARK REFERENCE PIXEL OVERSAMPLING

(71) Applicant: SEMICONDUCTOR COMPONENTS INDUSTRIES, LLC, Phoenix, AZ (US)

(72) Inventor: Peter SPIESSENS, Werchter (BE)

(73) Assignee: SEMICONDUCTOR COMPONENTS INDUSTRIES, LLC, Phoenix, AZ (US)

(21) Appl. No.: 16/948,802

(22) Filed: Oct. 1, 2020

Related U.S. Application Data
(60) Provisional application No. 62/705,664, filed on Jul. 9, 2020.

(51) Int. Cl. H04N 5/361; H04N 5/378; H03M 1/08; H04N 5/369

(52) U.S. Cl. CPC H04N 5/361; H04N 5/36963; H03M 1/08; H04N 5/378

(57) ABSTRACT

An image sensor may include an array of image pixels arranged in rows and columns. A first portion of the array may include active pixels that are read out using first analog-to-digital converter (ADC) circuits. A second portion of the array may include dark reference pixels that are read out using second analog-to-digital converter (ADC) circuits. The first ADC circuits may have a first sampling rate, a first resolution, and a first size. The second ADC circuits may have an oversampling rate that is greater than the first sampling rate, a second resolution that is greater than the first resolution, and a second size that is bigger than the first size. Configured in this way, the second ADC circuits may perform averaging of a row noise via direct time-domain oversampling, which can help dramatically reduce the number of dark reference pixel columns in the array.

### CROSS-REFERENCE TO RELATED APPLICATIONS

This application claims the benefit of U.S. Provisional Patent Application No. 62/705,664, filed on Jul. 9, 2020, the entire contents of which is incorporated herein by reference.

### BACKGROUND

This relates generally to imaging devices, and more particularly, to image sensors with dark reference pixels.

Image sensors are commonly used in electronic devices such as cellular telephones, cameras, and computers to capture images. In a typical arrangement, an electronic device is provided with an array of image pixels arranged in pixel rows and pixel columns. Each image pixel in the array includes a photodiode that is coupled to a floating diffusion region via a transfer gate. Row control circuitry is coupled to each pixel row for resetting, initiating charge transfer, or selectively activating a particular row of pixels for readout. Column circuitry is coupled to each pixel column for reading out pixel signals from the image pixels.

The image pixel array is read out on a row-by-row basis. The readout of each row of pixels in the array may be adversely impacted by the associated row noise of each pixel row. This row noise can result in row-to-row variation or even frame-to-frame variation, which can be detected by the human eye and is thus a key optical performance indicator for an image sensor. Conventionally, row noise is mitigated by reading out signals from a large number of dark reference pixels per row and then averaging all of the signals read out from the dark reference pixels. To achieve an acceptable row noise ratio, image sensors would typically require hundreds of dark reference pixel columns in each pixel row. Requiring such a large number of dark reference columns per row, however, takes up a significant amount of semiconductor area in an image sensor die.

It is within this context that the embodiments described herein arise.

### BRIEF DESCRIPTION OF THE DRAWINGS

FIG. 1 is a diagram of an illustrative electronic device having an image sensor in accordance with an embodiment.

FIG. 2 is a diagram of an illustrative pixel array and associated row and column control circuitry for reading out image signals from an image sensor in accordance with an embodiment.

FIG. 3 is a diagram of an illustrative pixel array having active pixels read out using first data converters and dark reference pixels read out using second data converters with a higher sampling rate in accordance with an embodiment.

FIG. 4 is a diagram showing an illustrative row of image pixels sharing a power supply line in accordance with an embodiment.

FIG. 5 is a diagram of an illustrative dark reference pixel that is read out using an oversampling analog-to-digital converter in accordance with an embodiment.

FIG. 6 is a flow chart of illustrative steps for operating a pixel array of the type shown in FIGS. 3-5 in accordance with an embodiment.

FIG. 7 is a plot illustrating a tradeoff between spatial averaging versus time domain oversampling/averaging in accordance with an embodiment.

### DETAILED DESCRIPTION

Embodiments of the present invention relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds or thousands or millions of pixels (e.g., megapixels). Image sensors may include control circuitry such as circuitry for operating the pixels and readout circuitry for reading out image signals corresponding to the electric charge generated by the photosensitive elements.

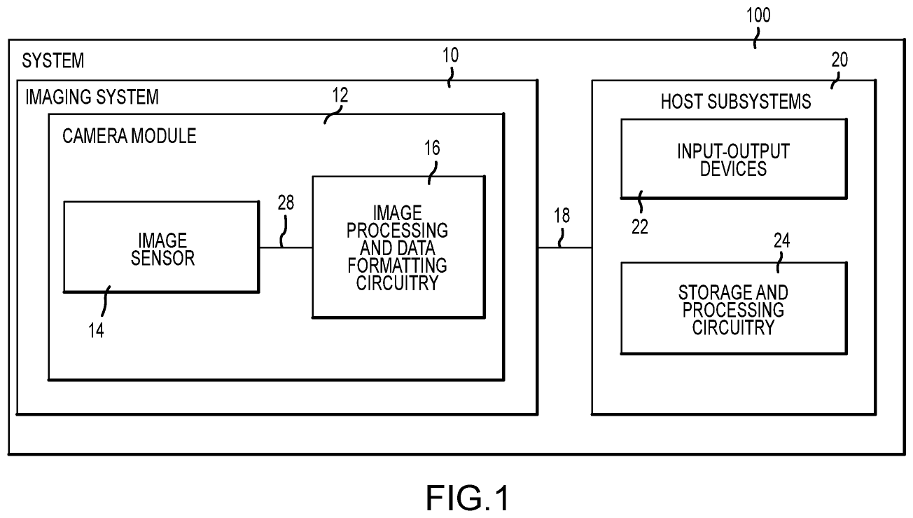

FIG. 1 is a diagram of an illustrative imaging and response system including an imaging system that uses an image sensor to capture images. System 100 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses.

Each image sensor in camera module 12 may be identical or there may be different types of image sensors in a given image sensor array integrated circuit. During image capture operations, each lens may focus light onto an associated image sensor 14. Image sensor 14 may include photosensitive elements (i.e., image sensor pixels) that convert the light into digital data. Image sensors may have any number of pixels (e.g., hundreds, thousands, millions, or more). A typical image sensor may, for example, have millions of pixels (e.g., megapixels). As examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), address circuitry, etc.

Still and video image data from camera sensor 14 may be provided to image processing and data formatting circuitry 16 via path 28. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SoC) arrangement, camera sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Host subsystem 20 may include processing software for detecting objects in images, detecting motion of objects between image frames, determining distances to objects in images, filtering or otherwise processing images provided by imaging system 10.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

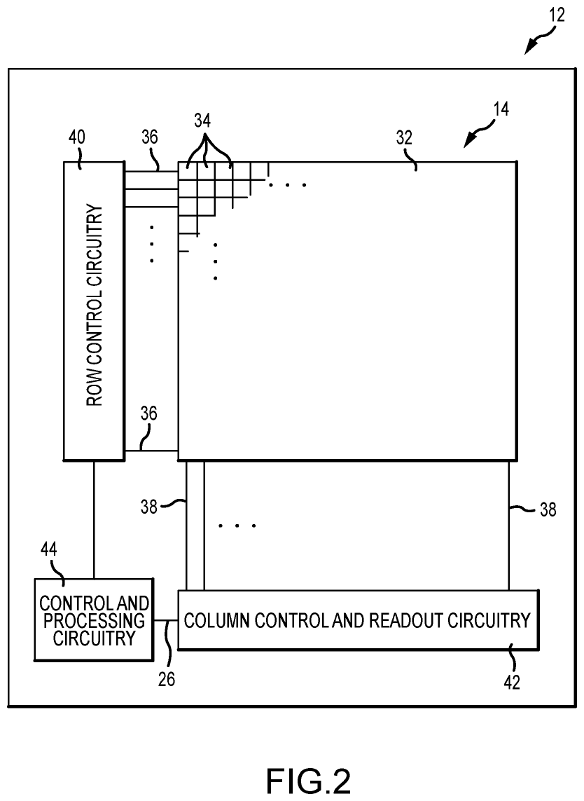

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic) may sometimes be considered part of image processing and data formatting circuitry 16 in FIG. 1. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuits 42 via data path 26. Row control circuitry 40 may receive row addresses from control and processing circuitry 44 and may supply corresponding row control signals to image pixels 34 over control paths 36 (e.g., pixel reset control signals, charge transfer control signals, blooming control signals, row select control signals, dual conversion gain control signals, or any other desired pixel control signals).

Column control and readout circuitry 42 may be coupled to the columns of pixel array 32 via one or more conductive lines such as column lines 38. Column lines 38 may be coupled to each column of image pixels 34 in image pixel array 32 (e.g., each column of pixels may be coupled to a corresponding column line 38). Column lines 38 may be used for reading out image signals from image pixels 34 and for supplying bias signals (e.g., bias currents or bias voltages) to image pixels 34. During image pixel readout operations, a pixel row in image pixel array 32 may be selected using row driver circuitry 40 and image data associated with image pixels 34 of that pixel row may be read out by column readout circuitry 42 on column lines 38. Column readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and column memory for storing the read out signals and any other desired data. Column control and readout circuitry 42 may output digital pixel readout values to control and processing logic 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

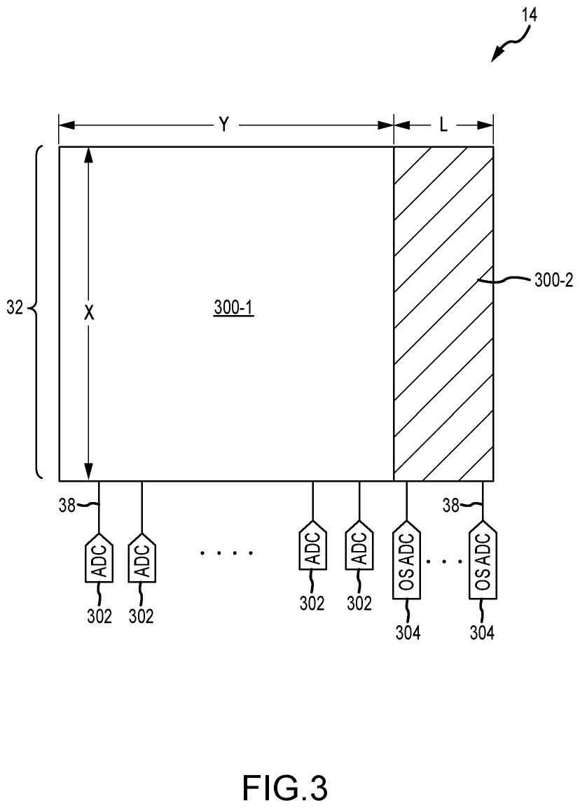

As described in the background section, an image sensor pixel array may be subject to row noise when reading out signals on a row-by-row basis. To mitigate row noise, image sensor 14 may be provided with dark reference pixels configured to enable row noise estimation in the time domain in accordance with an embodiment (see, e.g., FIG. 3). As shown in FIG. 3, image sensor 14 may include an image sensor array 32 having a first portion 300-1 of active image sensor pixels configured to receive ambient light from a scene and to generate a corresponding amount of charge and also a second portion 300-2 of dark reference pixels. The dark reference pixels in portion 300-1 of the image sensor array 32 may be “optically black” pixels (e.g., pixels that do not receive light such as pixels covered by a metal shield, a light shield, or other optically opaque shielding structure) or may be “electrically black” pixels (e.g., pixels in which the reset gate is always on during normal operation and in which the charge transfer gate is always off). The dark reference pixels may therefore sometimes be referred to as dark pixels, reference pixels, black pixels, optically black pixels, shielded pixels, electrically black pixels, etc. In general, any type of dark reference pixels may be used in portion 300-2.

In the example of FIG. 3, image sensor array 32 has X number of row, where the active imaging portion 300-1 has Y pixel columns and where the dark reference portion 300-2 has L pixel columns. The Y active pixel columns may be read out using Y corresponding data converters such as analog-to-digital converter (ADC) circuits 302, whereas the L dark reference pixel columns may instead be read out using L corresponding data converters such as analog-to-digital converter (ADC) circuits 304. Data converters 302 may have a first sampling rate, whereas data converters 304 may have a second sampling rate that is greater than the first sampling rate. For example, data converters 302 might be implemented as ramp ADCs or successive approximation ADCs that require sampling circuits at their inputs. In contrast, data converters 304 may be implemented as a different type of ADCs such oversampling (OS) ADCs, including but not limited to sigma-delta (ΣΔ) ADC circuits. Data converter 304 might be implemented as a discrete time ΣΔ ADC or a continuous time ΣΔ ADC (as examples). In general, data converters 304 may be implemented using any suitable type of oversampling ADC circuit. The term “oversampling” refers to the property that converters 304 should exhibit a greater sampling rate than that of converters 302. Data converters 302 and 304 may therefore sometimes be referred to as being different types of ADC circuits. These examples are merely illustrative. If desired, data converters 302 might also be implemented using sigma-delta ADC circuits.

Data converters 304 may also be bigger in size than data converters 302. Moreover, data converters 302 may have a first resolution, whereas data converters 304 may have a second resolution that is greater than the first resolution of data converters 302. For example, each of data converters 302 may be a 10-bit or 12-bit ADC, whereas each of data converters 304 may be a 14-bit, 15-bit, or 16-bit ADC. In general, data converters 302 may be implemented as N-bit ADCs while data converters may be implemented as (N+M)-bit ADCs, where M can be equal to 1, 2, 3, 4, 5, 6, 7, 8, 9, 10, more than 10, or any suitable integer greater than or equal to one. The use of oversampling ADC circuits 304 in reading out the dark reference pixels serves to average out pixel-wise read noise in the time domain, as opposed to the conventional spatial averaging technique that requires hundreds of redundant dark pixel columns. Using oversampling ADC circuits 304 to read out dark pixels in this way can help reduce the row noise ratio by a factor of 2\ddot{ }M, thus reducing the required number of dark reference pixels by 2\hat{ }(2*M).

Consider an example where the target row noise ratio is 1/16. The traditional row noise estimation approach that relies on averaging in the spatial domain might require 256 (i.e., 16\hat{ }2) dark reference pixel columns. In a suitable arrangement where data converters 302 are 10-bit ADCs while data converters 304 are 14-bit oversampling ADCs (e.g., M=4), the required amount of dark reference pixels would be reduced by a factor of 2\hat{ }4 or 16 while achieving the target row noise ratio. As a result, instead of needing 256 dark reference pixel columns, only one dark reference pixel column and thus one corresponding ADC 304 are needed.

In another suitable arrangement where data converters 302 are 12-bit ADCs while data converters 304 are 16-bit oversampling ADCs (e.g., M=4), the required amount of dark reference pixels would again be reduced by a factor of 2\hat{ }4 or 16 (yet achieving the target row noise ratio). Similarly, instead of needing 256 dark reference pixel columns, only one dark reference pixel column and thus one corresponding ADC 304 are needed.

In yet another suitable arrangement where data converters 302 are 12-bit ADCs while data converters 304 are 14-bit oversampling ADCs (e.g., M=2), the required amount of dark reference pixels would be reduced by a factor of 2\hat{ }2 or 4 (yet achieving the target row noise ratio). Thus, instead of needing 256 dark reference pixel columns, only 16 dark reference pixel columns and corresponding ADCs 304 are needed.

As illustrated by these examples, the use of oversampling the dark reference signals to perform signal averaging in the time domain can significantly reduce the amount of area overhead required for the dark reference pixel portion, thus dramatically reducing product cost. The examples above in which the number of dark pixel columns L is equal to one and 16 are merely illustrative and are not intended to limit the scope of the present embodiments. In general, this technique may enable pixel array 32 to have far fewer dark pixel columns relative to conventional pixel arrays configured to reduce row noise, where L can be 1-10, 10-50, 50-100, less than 100, less than 64, less than 32, less than 16, less than 8, less than 4, less than 2, etc.

Furthermore, the example of FIG. 3 in which the active pixel portion 300-1 and the dark pixel portion 300-2 are separate contiguous portions within array 32 is merely illustrative. If desired, one or more dark reference pixel columns may be interleaved with the active pixel columns. For example, array 32 may have alternating active pixel columns and dark pixel columns. As another example, one dark pixel column may be interspersed between every group of two or more active pixel columns. As yet another example, multiple dark pixel columns may be interposed between every group of two or more continuous active pixel columns.

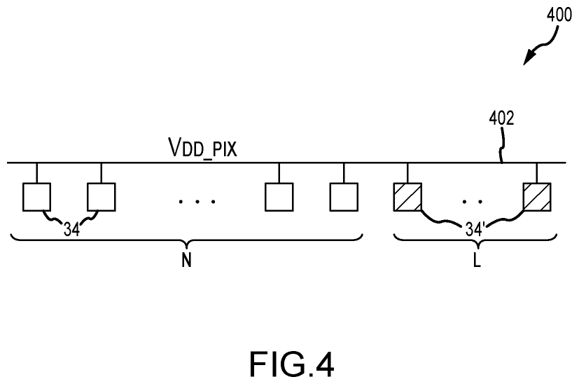

FIG. 4 is a diagram showing an illustrative row 400 of pixels sharing a power supply line in accordance with an embodiment. As shown in FIG. 4, pixel row 400 may have N active pixels 34 and L dark reference pixels 34′ coupled to a shared power supply line 402 (e.g., a positive power supply terminal on which positive power supply voltage VDD_PIX is provided). The method of using time-domain oversampling of the dark reference pixels described in connection with FIG. 3 may take into account the noise in power supply line 402. In addition to accounting for such power supply noise, any other biasing voltage or current that is supplied to two or more pixels in row 400 may also be taken into account or averaged using via the time-domain oversampling operation. In other words, row noise due to power supply noise and other bias noise may be mitigated when estimating a row noise correction term using the oversampling ADCs 304.

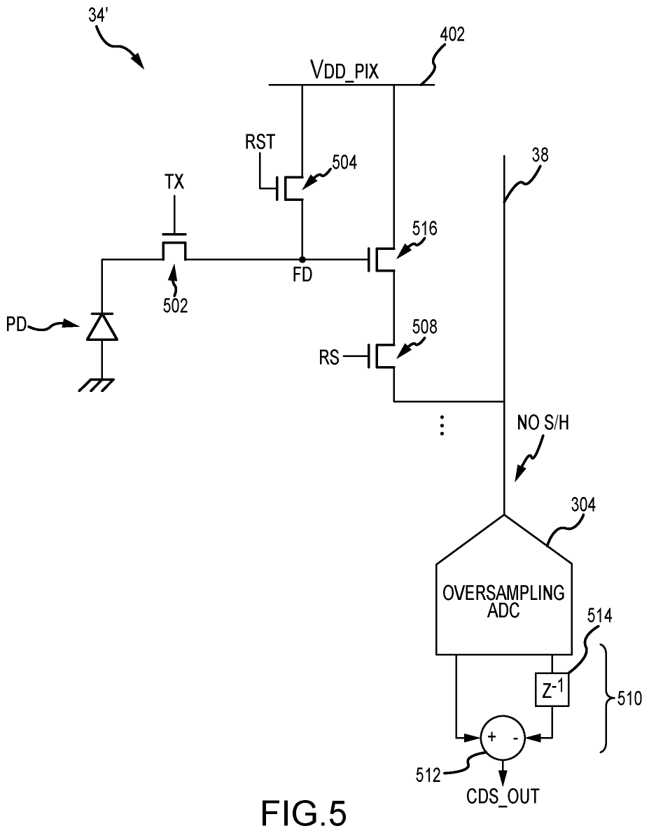

FIG. 5 is a diagram of an illustrative dark reference pixel 34′ that is read out using oversampling ADC circuit 304. As shown in FIG. 5, dark reference pixel 34′ may include a photodiode PD, a floating diffusion node FD (sometimes referred to as a floating diffusion region), a charge transfer transistor 502 coupled between the photodiode PD and the floating diffusion node FD, a reset transistor 504 coupled between power supply line 402 and the floating diffusion node FD, a source follower transistor 506 having a drain terminal connected to the power supply line 402, a gate terminal connected to the floating diffusion node FD, and a source terminal, a row select transistor 508 and is coupled between the source terminal of the source follower transistor 506 and a corresponding pixel output column line 38.

In one suitable arrangement, dark reference pixel 34′ may be an optically black pixel (e.g., a pixel that does not receive ambient light such as a pixel covered by a metal shield, a light shield, or other optically opaque shielding structure). In another suitable arrangement, dark reference pixel 34′ may be an electrically black pixel, where charge transfer gate control signal TX is never asserted (i.e., so that transfer gate 502 is never turned on) and where the reset gate control signal RST is always asserted (i.e., so that the reset gate 504 is always activated or shorted to VDD_PIX. In yet another suitable arrangement, dark reference pixel 34′ might be both an optically black pixel and an electrically black pixel.

The example of FIG. 5 in which dark reference pixel 34′ has four transistors is merely illustrative and is not intended to limit the scope of the present embodiments. If desired, dark reference pixel 34′ may have a similar pixel structure as an active pixel 34, may have more than four pixel transistors, may have one or more additional capacitors, may be implemented to optionally support a rolling shutter operation or a global shutter operation, and/or may have other suitable structure. In general, dark reference pixel 34′ may sometimes be referred to as a dark pixel, a reference pixel, a black pixel, an optically black pixel, a shielded pixel, an electrically black pixel, etc.

Still referring to FIG. 5, dark reference pixel 34′ may be coupled to a corresponding oversampling ADC circuit 304 via column line 38. In particular, pixel column line 38 may optionally be directly connected to the input of oversampling ADC 304 such that no sample-and-hold (S/H) circuit sits before the ADC conversion. This direct connection with the lack of S/H circuits at the input of converter 304 may allow for the signal averaging in the time domain when determining the row noise correction term.

Additional circuitry such as circuitry 510 may be configured to compute a correlated double sampling (CDS) output. For example, circuitry 510 may include a digital subtraction circuit 512 having a first (positive) input that receives a first reset signal from oversampling ADC 304 and a second (negative) input that receives a second reset signal from oversampling ADC 304 via delay circuit 514. Configured in this way, circuitry 512 may be configured to compute a corresponding noise output CDS_OUT representing a time-domain-averaged row noise correction term. This particular CDS implementation of FIG. 5 is merely illustrative. In general, other types of CDS circuitry may be implemented after oversampling ADC 304. If desired, the CDS computation might also be implemented in the analog domain prior to conversion by ADC 304.

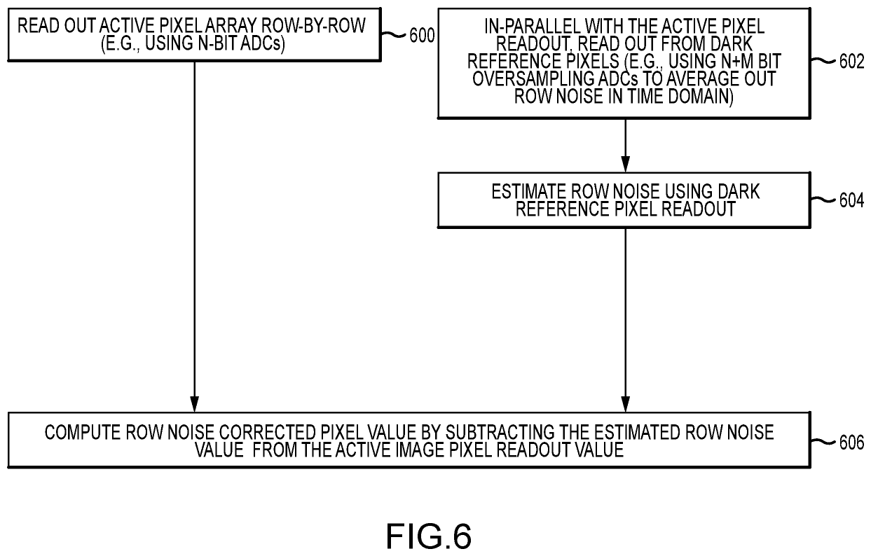

FIG. 6 is a flow chart of illustrative steps for operating pixel circuitry of the type shown in FIGS. 3-5. At step 600, the active pixel array portion may be read out row-by-row using the N-bit ADC converters 302. While the active pixel array is being read out, the dark reference pixel portion may also be read out row-by-row (e.g., using the N+M bit oversampling ADC converters 304 for averaging the pixel-wise read out in the time domain).

Data converters 302 might be implemented as ramp ADCs or successive approximation ADCs that require sampling circuits at their inputs. In contrast, data converters 304 may be implemented as oversampling (OS) ADCs such as sigma-delta (ΣΔ) ADC circuits or other suitable types of oversampling ADC circuit. If desired, data converters 302 might also be implemented as sigma-delta ADC circuits. In general, data converter 304 may have a higher data sampling rate and higher resolution than data converter 302. Integer N may be 8, 10, 12, 14, or any suitable value for typical imaging applications, whereas integer M may be 1, 2, 3, 4, 5, or other suitable values greater than or equal to one.

At step 604, an estimated row noise correction value may be obtained using the oversampled values read out from the dark reference pixels. The amount of oversampling (i.e., the additional M bit of resolution of data converter 304) helps to dramatically decrease the number of required dark reference pixel columns by a factor of M\hat{ }2.

At step 606, a row noise corrected pixel value may be computed for each pixel by subtracting out the estimated row noise correction value obtained at step 604 from the active image pixel value read out during step 600. The estimated row noise value may be the same for each pixel along a given row. The estimated row noise value may be different or may be the same from row-to-row. Computing row noise corrected pixel values in this way may therefore provide improved area efficiency since the number of required reference pixel columns can be less than 100, less than 50, less than 10, or even as low as one.

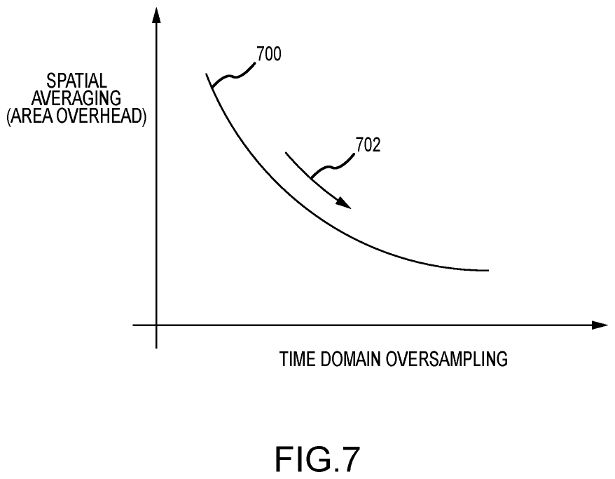

The methods and apparatus described in connection with FIGS. 3-6 trade time-domain oversampling for spatial complexity/redundancy in terms of the required number of dark reference pixel columns to obtain a target row noise ratio. FIG. 7 is a plot illustrating such tradeoff. As shown in FIG. 7, curve 700 exhibits high area overhead when the oversampling amount is fairly low (i.e., when M is 0 or 1). Curve 700 decreases dramatically to reduce the area overhead as the amount of time-domain oversampling increases (e.g., when M is 2, 3, 4, or greater), as shown by arrow 702. In other words, curve 700 illustrates how using direct time-domain oversampling can be more beneficial than conventional spatial averaging schemes that require hundreds of dark pixel columns.

The foregoing is merely illustrative of the principles of this invention and various modifications can be made by those skilled in the art without departing from the scope and spirit of the invention. The foregoing embodiments may be implemented individually or in any combination.

What is claimed is:

1. An image sensor, comprising:
active pixels configured to receive light;
dark reference pixels;
first analog-to-digital converter (ADC) circuits configured to receive signals from the active pixels and configured to operate at a first sampling rate; and
second analog-to-digital converter (ADC) circuits configured to receive signals from the dark reference pixels and configured to operate at a second sampling rate greater than the first sampling rate.

2. The image sensor of claim 1, wherein the dark reference pixels comprise optically black pixels.

3. The image sensor of claim 1, wherein the dark reference pixels comprise electrically black pixels.

4. The image sensor of claim 1, wherein the second ADC circuits comprise oversampling analog-to-digital converters.

5. The image sensor of claim 4, wherein the second ADC circuits comprise sigma-delta analog-to-digital converters.

6. The image sensor of claim 4, wherein the first and second ADC circuits are different types of analog-to-digital converters.

7. The image sensor of claim 1, wherein the first ADC circuits exhibit a first resolution, and wherein the second ADC circuits exhibit a second resolution that is greater than the first resolution.

8. The image sensor of claim 1, wherein the first ADC circuits exhibit a first size, and wherein the second ADC circuits exhibit a second size that is larger than the first size.

9. The image sensor of claim 1, wherein the second ADC circuits are used to read signals out from the dark reference pixels to obtain an estimated row noise correction value.

10. The image sensor of claim 1, wherein sample-and-hold circuits are formed at inputs of the first ADC circuits, and wherein no sample-and-hold circuits are formed at inputs of the second ADC circuits.

11. The image sensor of claim 1, wherein the dark reference pixels form less than 100 dark reference pixel columns in the image sensor.

12. The image sensor of claim 1, wherein the dark reference pixels form less than 50 dark reference pixel columns in the image sensor.

13. The image sensor of claim 1, wherein the dark reference pixels form less than 10 dark reference pixel columns in the image sensor.

14. The image sensor of claim 1, wherein the dark reference pixels form only one dark reference pixel column in the image sensor.

15. A method of operating an image sensor, comprising:
using active pixels to receive light;
using dark reference pixels to estimate noise;
using first analog-to-digital converters (ADCs) to receive signals from the active pixels, wherein the first ADCs have a sampling rate; and
using second analog-to-digital converters (ADCs) to receive signals from the dark reference pixels, wherein the second ADCs have an oversampling rate that is greater than the sampling rate of the first ADCs.

16. The method of claim 15, wherein using the second ADCs to receive signals from the dark reference pixels with the oversampling rate comprises averaging out the noise in the time domain to reduce the number of dark reference pixels in the image sensor.

17. The method of claim 15, wherein the first ADCs receive signals from the active pixels while the second ADCs receive signals from the dark reference pixels.

18. The method of claim 15, further comprising:
using the first ADCs to compute active pixel readout values;
using the second ADCS to estimate the noise; and
computing noise corrected pixel values by subtracting the estimated noise from the active pixel readout values.

19. Imaging circuitry, comprising:
a pixel configured to receive light;
a dark pixel;
a first analog-to-digital converter (ADC) configured to receive signals from the pixel, wherein the first ADC has a first resolution; and
a second analog-to-digital converter (ADC) configured to receive signals from the dark pixel, wherein the second ADC has a second resolution that is different than the first resolution.

20. The imaging circuitry of claim 19, wherein the second resolution of the second ADC is greater than the first resolution of the first ADC.

21. The imaging circuitry of claim 19, wherein the second ADC is an oversampling analog-to-digital converter.
